(19) United States
(12) Patent Application Publication
(10) Pub. No.: US 2013/0192055 A1
(43) Pub. Date: Aug. 1, 2013

(54) METHOD FOR PRODUCING DISPLAY DEVICE

(71) Applicant: Panasonic Corporation, Osaka (JP)

(72) Inventors: Hisanori Sasaki, Osaka (JP); Shigeru Aruga, Osaka (JP)

(73) Assignee: Panasonic Corporation, Osaka (JP)

(21) Appl. No.: 13/796,180

(22) Filed: Mar. 12, 2013

Related U.S. Application Data
(63) Continuation of application No. PCT/JP2012/001087, filed on Feb. 20, 2012.

(30) Foreign Application Priority Data
Feb. 22, 2011 (JP) 2011-035662

(51) Int. Cl. H05K 13/00

(52) U.S. Cl. CPC H05K 13/0023
USPC 29/592.1

(57) ABSTRACT

According to the present disclosure, a display device has a casing including a back cabinet, a flat type display panel placed in the casing, backlight device (4) arranged on a rear side of the flat type display panel, and a circuit board constituting a drive circuit for displaying an image on the flat type display panel. A space portion that can house therein backlight device (4) and the circuit board is provided in back cabinet (7), and backlight device (4) and the circuit board are housed in and mounted to back cabinet (7). Further, dummy panel (30) having a shape identical with that of the flat type display panel is placed in a position where the flat type display panel is supposed to be housed for packing and transporting the display device.

### TECHNICAL FIELD

The present disclosure relates to a method for manufacturing a display device such as a liquid crystal display device used for a television receiver or a monitor device.

### BACKGROUND ART

A demand for a liquid crystal display device as a flat type display device is increasing not only in home but also in business.

The liquid crystal display device in general includes a display module formed by arranging a backlight device as a surface light source on a rear side of a flat type liquid crystal display panel. This display module is housed inside a low-profile casing having a front cabinet and a back cabinet (refer to PLT1).

The liquid crystal display device is completed, for example, in the following manner. A panel manufacturer manufactures a liquid crystal display panel and supplies the panel to a finished product manufacturer such as a television set manufacturer. The finished product manufacturer produces a display module by combining the liquid crystal display panel and a backlight device as a surface light source together. The display module is housed together with a drive circuit board for the liquid crystal display panel in the low-profile casing having the front cabinet and the back cabinet. In this way, the liquid crystal display device is completed.

In addition, the finished product manufacturer constructs a factory for assembling a product in an area in which the liquid crystal display device is sold or in an area close thereto, and assembles and sells a finished product having a design and a function adapted to the sales area.

Under such circumstances, as a demand in a global scale increases, a reduction in the number of processes for assembling and easiness in assembling are demanded. Simplification in a packing method when the display module or the like is transported to an assembling factory is also demanded.

### CITATION LIST

### Patent Literature

PLT1: Unexamined Japanese Patent Publication No. 2009-139426

### SUMMARY DISCLOSURE

According to the present disclosure, a display device has a casing including a back cabinet, a flat type display panel placed in the casing, a backlight device arranged on a rear side of the flat type display panel, and a circuit board constituting a drive circuit for displaying an image on the flat type display panel. A space portion that can house therein the backlight device and the circuit board constituting a drive circuit for displaying an image on the flat type display panel is provided in the back cabinet. The backlight device and the circuit board are housed in and mounted to the back cabinet, a dummy panel having a shape identical with that of the flat type display panel is placed in a position where the flat type display panel is supposed to be housed for packing and transporting the display device.

### BRIEF DESCRIPTION OF DRAWINGS

FIG. 1 is a front view of an external appearance of a liquid crystal display device according to an embodiment of the present disclosure.

FIG. 2 is a perspective view illustrating a state of the liquid crystal display device from which a stand is removed.

FIG. 3 is a block diagram illustrating a circuit block of an entire configuration of the liquid crystal display device.

FIG. 4 is a plan view illustrating a state in which a back cabinet is removed for explaining a layout example of the circuit block of the liquid crystal display device.

FIG. 5 is a cross sectional view illustrating a state of the liquid crystal display device taken along line 5-5 of FIG. 2.

FIG. 6 is an enlarged view of section B of FIG. 5.

FIG. 7 is a perspective view illustrating disassembled sections of the liquid crystal display device.

FIG. 8 is a perspective view illustrating an inner wall surface of the back cabinet of the liquid crystal display device.

FIG. 9 is a perspective view illustrating a state in which a backlight device of the liquid crystal display device is disassembled.

FIG. 10A is a descriptive view for explaining a method for manufacturing a display device according to the present disclosure.

FIG. 10B is a descriptive view for explaining the method for manufacturing the display device according to the present disclosure.

FIG. 10C is a descriptive view for explaining the method for manufacturing the display device according to the present disclosure.

### DESCRIPTION OF EMBODIMENT

Hereinafter, a method for manufacturing a display device according to an embodiment of the present disclosure will be described with reference to the drawings by taking a display module used for a liquid crystal display device as an example.

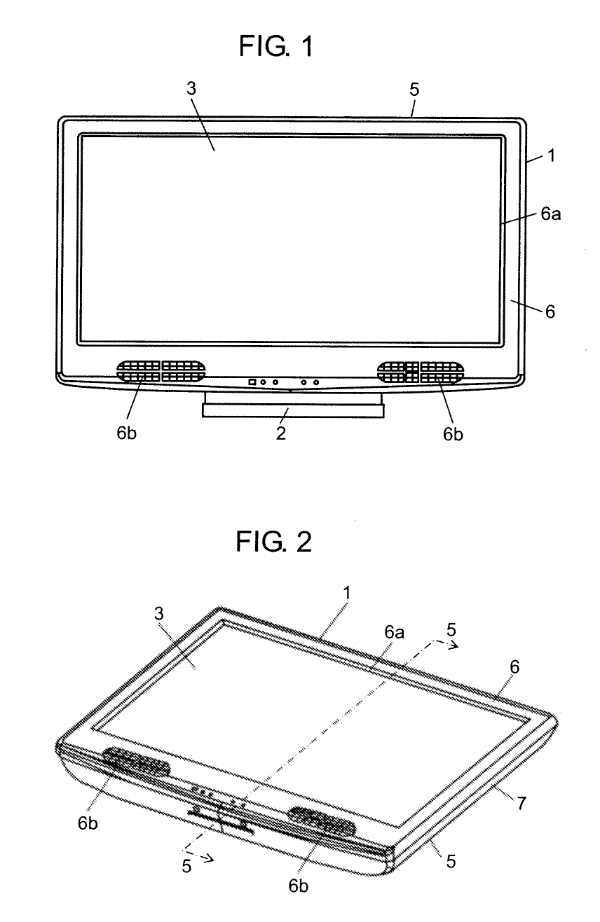

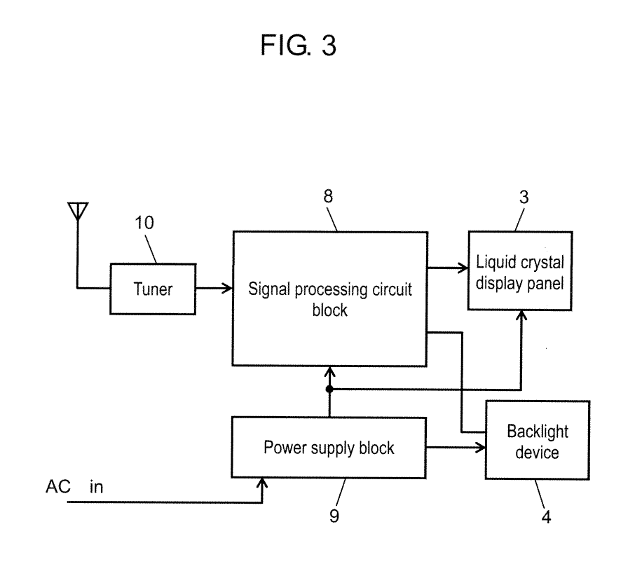

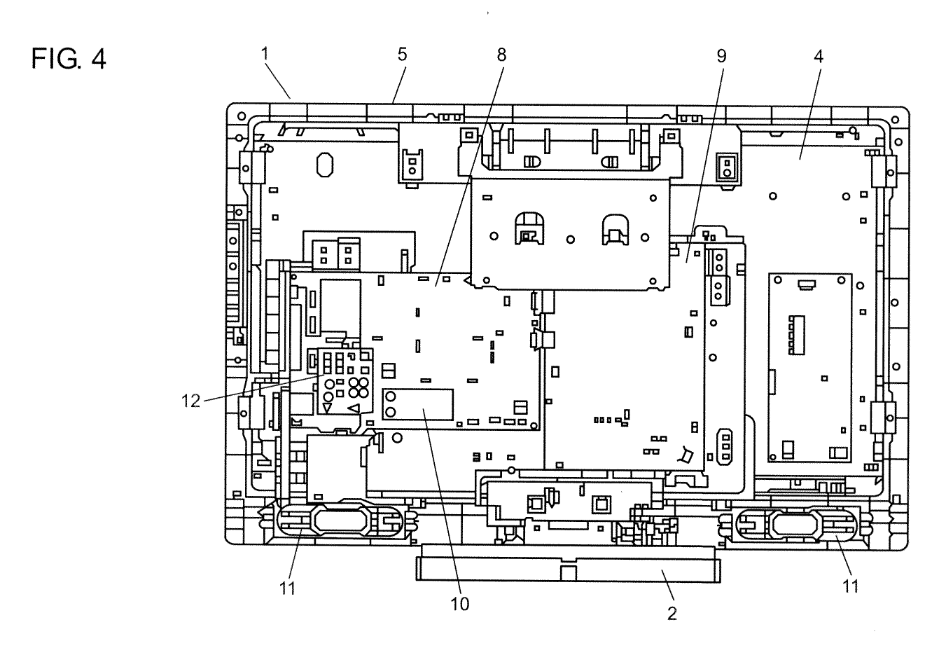

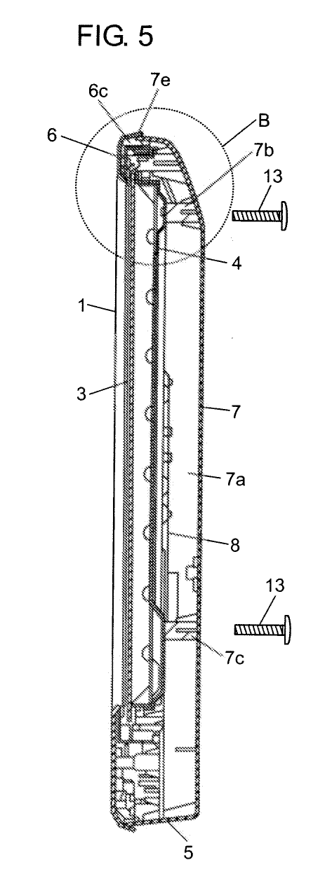

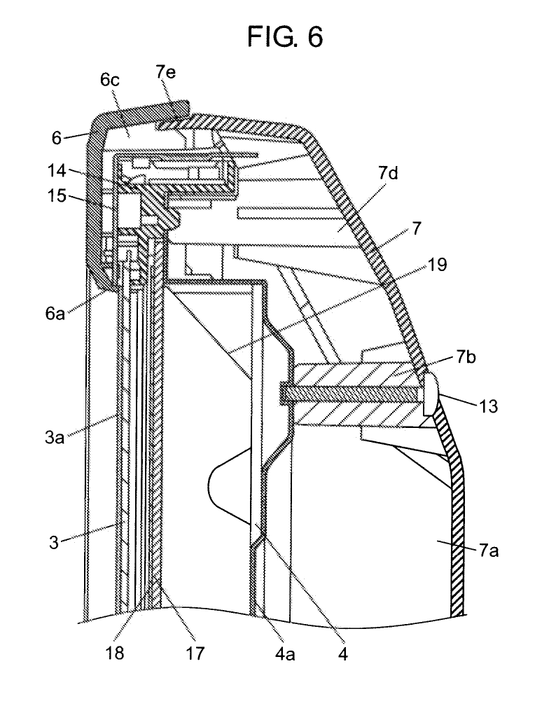

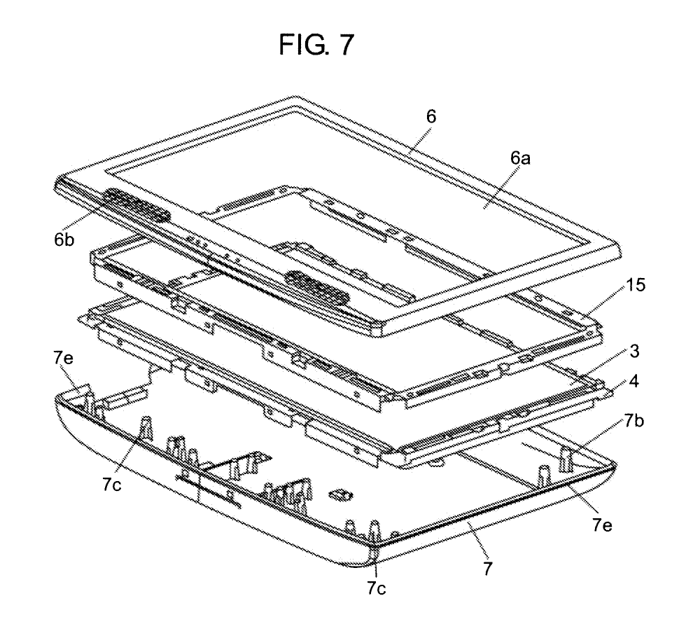

FIG. 1 is a front view of an external appearance of a liquid crystal display device according to an embodiment of the present disclosure; FIG. 2 is a perspective view illustrating a state of the liquid crystal display device from which a stand is removed; FIG. 3 is a block diagram illustrating a circuit block of an entire configuration of the liquid crystal display device; FIG. 4 is a plan view illustrating a state in which a back cabinet is removed for explaining a layout example of the circuit block of the liquid crystal display device; FIG. 5 is a cross sectional view illustrating a state of the liquid crystal display device taken along line 5-5 of FIG. 2; FIG. 6 is an enlarged view of section B of FIG. 5; and FIG. 7 is a perspective view illustrating disassembled sections of the liquid crystal display device.

First, as illustrated in FIGS. 1 and 2, the liquid crystal display device includes display device body 1, and stand 2 holding display device body 1 in an erected state. Display device body 1 is formed by housing a display module configured of liquid crystal display panel 3 as a flat type display panel and back light device 4 (illustrated in FIG. 5) into casing 5 made of a resin molded article or the like. Further, casing 5 is structured of front cabinet 6 and back cabinet 7. Front cabinet 6 is provided with opening 6a so as to correspond to an image display area of liquid crystal display panel 3, and back cabinet 7 is combined with front cabinet 6. Reference numeral 6b represents a speaker grill for sending sound of a speaker outside.

Also, as illustrated in FIGS. 3 and 4, the liquid crystal display device in its entirety includes, as an outline configuration, a drive circuit for displaying an image on liquid crystal display panel 3. Further, the liquid crystal display device is configured of signal processing circuit block 8 provided with a lighting control circuit for controlling lighting of backlight device 4, liquid crystal display panel 3, power supply block 9 for supplying power voltage to backlight device 4 and signal processing circuit block 8, tuner 10 for receiving television broadcast and supplying a received signal to signal processing circuit block 8, and speaker 11 for outputting sound. In addition, signal processing circuit block 8 and power supply block 9 are individually configured by mounting components for building circuits on circuit boards. Then, the circuit board with signal processing circuit block 8, power supply block 9, tuner 10, and the like mounted thereon is mounted so as to be arranged in space between a rear surface of backlight device 4 and back cabinet 7.

FIG. 3 is illustrated while the speaker is omitted. In FIG. 4, reference numeral 12 represents an external signal input terminal which is for inputting a video signal from external equipment such as a DVD player to the liquid crystal display device, and is mounted in signal processing circuit block 8.

Here, as illustrated in FIGS. 5 to 7, in the liquid crystal display device according to the present disclosure, back cabinet 7 includes space portion 7a which can house therein the display module configured of liquid crystal display panel 3 and backlight device 4, and the circuit board. Backlight support portions 7b and 7c for supporting backlight device 4 are provided on an inner bottom surface forming space portion 7a. Frame 4a of backlight device 4 is mounted to backlight support portions 7b and 7c with screws 13.

A peripheral edge portion of an inner bottom surface of back cabinet 7 is provided with panel support portion 7d for holding panel support member 14 made of a resin molded article and supporting an outer peripheral edge portion of liquid crystal display panel 3. The outer peripheral edge portion of liquid crystal display panel 3 is supported by panel support member 14, and the outer peripheral edge portion of liquid crystal display panel 3 is pressed to panel support member 14 by frame 15 made of metal and having a substantially L-shape in cross section, so that liquid crystal display panel 3 is housed and arranged in a peripheral edge portion of an opening of space portion 7a of back cabinet 7. Here, reference numeral 3a represents a deflection film adhered to a display surface of liquid crystal display panel 3.

Here, liquid crystal panel 3 disposed in the opening of space portion 7a of back cabinet 7 is electrically connected to the circuit board constituting the drive circuit disposed on a rear side of backlight device 4 through a flexible wiring board (not illustrated) which is arranged along an outer circumference of backlight device 4.

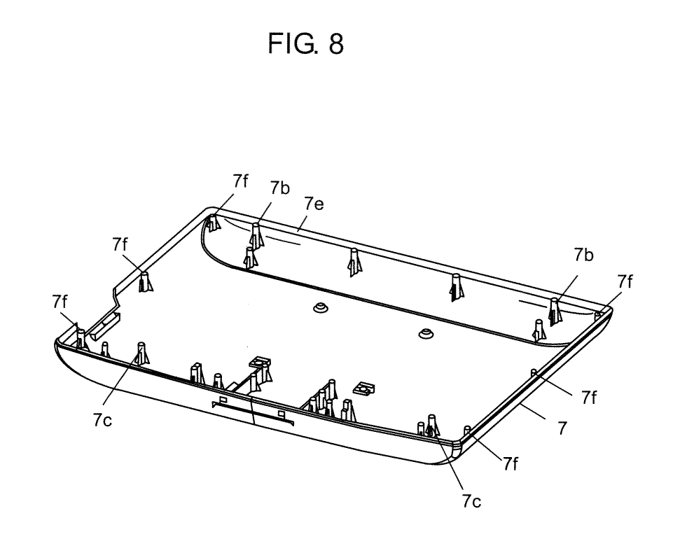

Further, as illustrated in FIG. 6, back cabinet 7 is mounted, through outer peripheral front end portion 7e thereof, to mounting piece 6c provided on an inner wall surface of front cabinet 6. Further, front cabinet 6 is mounted to back cabinet 7 with screws from a side of front cabinet 6, so that the casing that houses the display module and the circuit board with the drive circuit mounted therein is formed. FIG. 8 illustrates an inner wall surface of back cabinet 7, and front cabinet 6 is mounted to boss portions 7f provided on an outer periphery of back cabinet 7 with screws.

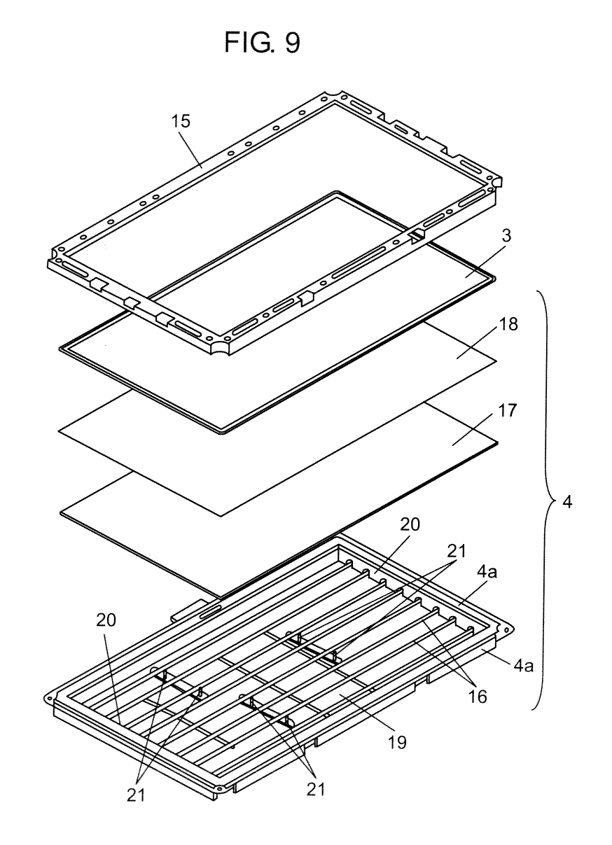

FIG. 9 is a perspective view illustrating a state in which the backlight device of the liquid crystal display device is disassembled. As illustrated in FIG. 9, backlight device 4 is to illuminate liquid crystal display panel 3 from a rear side thereof. Specifically, a plurality of linear light sources 16 arranged in frame 4a to become parallel to the liquid crystal panel 3, and diffuser panel 17 arranged in a manner to cover frame 4a are provided. Optical sheet 18 such as a prism sheet for diffusing or converging light that has passed through diffuser panel 17 is laminated on diffuser panel 17. Reflection sheet 19 formed of a metallic foil or the like and reflecting light emitted from linear light sources 16 toward a side of diffuser panel 17 is arranged on an inner bottom surface of frame 4a in a manner to substantially entirely cover the inner bottom surface, and a pair of support members 20 for holding linear light sources 16 are spaced away from each other in a direction in which linear light sources 16 extend and are arranged on the inner bottom surface.

Here, straight tube cold cathode fluorescent lamps (CCFL) are used as linear light sources 16, and are laid in parallel to one another. Both ends of linear light sources 16 are covered with support members 20. In addition, frame 4a is made of a resin or a metal such as aluminum, and has a box shape opening in one direction. Frame 4a in a box shape has a bottom wall forming a bottom surface parallel to an arrangement plane of linear light sources 16, and side walls rising from a periphery of the bottom wall. Further, a plurality of diffuser panel support members 21 for supporting diffuser panel 17 are arranged on the inner bottom surface of frame 4a.

Diffuser panel 17 is laid between linear light sources 16 and liquid crystal display panel 3, diffuses light incident from an incident surface thereof on a side of linear light sources 16, and emits the diffused light from an exit surface thereof on a side of liquid crystal display panel 3. Diffuser panel 17 is formed by injection molding using a transparent resin such as polystyrene or polycarbonate. Specifically, as illustrated in FIG. 9, diffuser panel 17 is arranged on a side opposite to reflection sheet 19 across linear light sources 16. Further, diffuser panel 17 has the incident surface allowing direct light from linear light sources 16 and reflected light from reflection sheet 19 to enter, and the exit surface allowing light diffused therein to exit therefrom. A plurality of layers of optical sheet 18 are laminated on the exit surface.

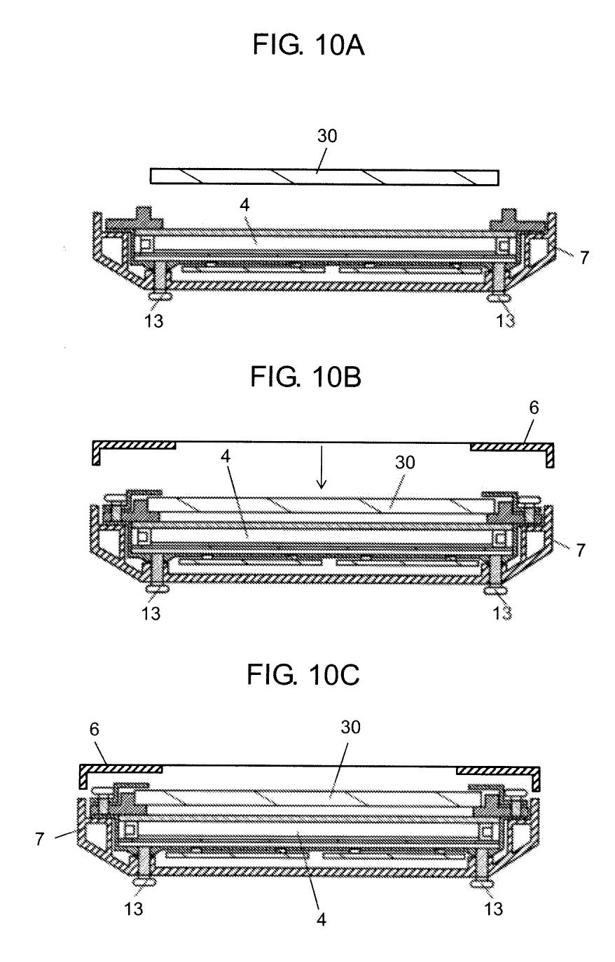

FIGS. 10A to 10C are descriptive views for explaining a method for manufacturing the display device according to the present disclosure.

As described above, the display device according to the present disclosure is provided, in back cabinet 7 thereof, with space portion 7a which can house therein back light device 4, liquid crystal display panel 3, and the circuit board that forms the drive circuit for displaying an image on liquid crystal display panel 3. As illustrated in FIG. 10A, back light device 4 and the circuit board are housed and mounted inside back cabinet 7. As illustrated in FIG. 10B, dummy panel 30 formed of a resin plate having a shape identical with that of liquid crystal display panel 3 is disposed in a position where liquid crystal display panel 3 is housed. As illustrated in FIG. 10C, by mounting front cabinet 6, backlight device 4, the circuit board, and casing 5 are packed. In contrast, liquid crystal panel 3 is separately packed and transported so that damage during transportation or the like can be prevented.

After these are separately packed and transported, when the display device is assembled, front cabinet 6 is removed, and dummy panel 30 mounted to back cabinet 7 is removed in a sequence opposite to the procedures described with reference to FIGS. 10A to 10C. Thereafter, the display device is completed by mounting liquid crystal display panel 3, electrically connecting liquid crystal display panel 3 and the circuit board to each other, and subsequently mounting front cabinet 6, in the sequence illustrated in FIGS. 10A to 10C. Dummy panel 30 may be collected and reused after removing. Although dummy panel 30 has a shape identical with that of liquid crystal display panel 3, this means that the shapes are identical in the sense of a rectangular shape or a square shape. It is needless to say that dummy panel 30 has a different shape for terminals or the like for electrical connection of liquid crystal display panel 3. In addition, although it is preferable that dummy panel 30 have dimensions identical with those of liquid crystal display panel 3, dummy panel 30 may not necessarily have dimensions exactly identical with those of liquid crystal display panel 3.

Broadcast systems, preferred image qualities, and designs are different according to sales areas, and therefore it is necessary to supply a product appropriate to the customers in such sales areas. By employing a manufacturing method involving packing, transportation, and assembling as in the case of the present disclosure, it is possible to provide an effect of easily transporting supplied components when a product in accordance with the customers in the sales area is assembled in the sales area.

In this way, according to the present disclosure, a display device has a casing including a back cabinet, a flat type display panel placed in the casing, a backlight device arranged on a rear side of the flat type display panel, and a circuit board constituting a drive circuit for displaying an image on the flat type display panel. A space portion that can house therein the backlight device, the flat type display panel, and the circuit board constituting a drive circuit for displaying an image on the flat type display panel is provided in the back cabinet. The backlight device and the circuit board are housed in and mounted to the back cabinet, a dummy panel having a shape identical with that of the flat type display panel is placed in a position where the flat type display panel is supposed to be housed for packing and transporting the display device. Accordingly, it is possible to provide an effect in which the flat type display panel is prevented from being damaged, and separate packing materials are not required for packing the backlight device and the circuit board.

Further, the flat type display panel is separately packed and transported, the dummy panel mounted to the back cabinet is removed when the display device is assembled, and thereafter the flat type display panel is mounted. For this reason, based on the back cabinet that was used for transportation, the back light device, the flat type display panel, the circuit board are sequentially assembled together in the back cabinet, and the front cabinet is mounted so that the final product can be assembled. Accordingly, as compared with the case where components are separately packed and transported, and then assembled together, it is possible to provide an effect of easier assembling.

### INDUSTRIAL APPLICABILITY

As described above, the present disclosure is useful in providing a display device that can be easily assembled.

### REFERENCE MARKS IN THE DRAWINGS

1 display device body

3 liquid crystal display panel

4 backlight device

5 casing

6 front cabinet

7 back cabinet

7a space portion

7b, 7c backlight support portion

7d panel support portion

14 panel support member

15 frame

30 dummy panel

1. A method for manufacturing a display device,
the display device comprising:
a casing including a back cabinet;
a flat type display panel placed in the casing;
a backlight device arranged on a rear side of the flat type display panel; and
a circuit board constituting a drive circuit for displaying an image on the flat type display panel,
the method comprising:
providing, in the back cabinet, a space portion that can house therein the backlight device and the circuit board;
housing and mounting the backlight device and the circuit board in and to the back cabinet; and
placing a dummy panel having a shape identical with that of the flat type display panel in a position where the flat type display panel is supposed to be housed for packing and transporting the display device.

2. A method for manufacturing a display device,
the display device comprising:
a casing including a back cabinet; a flat type display panel placed in the casing;
a backlight device arranged on a rear side of the flat type display panel; and
a circuit board constituting a drive circuit for displaying an image on the flat type display panel,
the method comprising:
providing, in the back cabinet, a space portion that can house therein the backlight device and the circuit board;
housing and mounting the backlight device and the circuit board in and to the back cabinet;
placing a dummy panel having a shape identical with that of the flat type display panel in a position where the flat type display panel is supposed to be housed for packing the display device;
separately packing and transporting the flat type display panel; and
removing the dummy panel fitted to the back cabinet when the display device is assembled and thereafter fitting the flat type display panel.
